(19) United States
(12) Patent Application Publication
(10) Pub. No.: US 2014/0077261 A1
(43) Pub. Date: Mar. 20, 2014

(54) POWER SEMICONDUCTOR DEVICE AND METHOD OF MANUFACTURING POWER SEMICONDUCTOR DEVICE

(71) Applicant: KABUSHIKI KAISHA TOSHIBA, Minato-ku (JP)

(72) Inventors: Yuichi Oshino, Tokyo (JP); Tomoko Matsudai, Tokyo (JP); Kazutoshi Nakamura, Himeji-Shi (JP); Shinichiro Misu, Tokyo (JP); Takuma Hara, Kamakura-Shi (JP)

(73) Assignee: KABUSHIKI KAISHA TOSHIBA, Minato-ku (JP)

(21) Appl. No.: 14/020,460

(22) Filed: Sep. 6, 2013

(30) Foreign Application Priority Data
Sep. 20, 2012 (JP) 2012-206811
Jul. 12, 2013 (JP) 2013-146968

(51) Int. Cl. H01L 29/739; H01L 29/66

(52) U.S. Cl. CPC H01L 29/7393; H01L 29/66325
USPC 257/140; 438/135

(57) ABSTRACT

An upper part of the termination region of the semiconductor substrate, an upper surface of the first diffusion layers and an upper surface of the first oxide film is etched in such a manner that the level of the upper surface of the semiconductor substrate in the termination region including the first oxide film and the first diffusion layers is lower than the level of the upper surface of the semiconductor substrate in the cell region. Then, a second oxide film is formed on the semiconductor substrate. An electrode is formed on the second oxide film so as to extend from the first region toward the cell region to the first diffusion layers in such a manner that the level of an upper surface of the electrode is lower than the level of the upper surface of the semiconductor substrate in the cell region.

### CROSS-REFERENCE TO RELATED APPLICATION

This application is based upon and claims the benefit of priority from the prior Japanese Patent Application No. 2012-206811, filed on Sep. 20, 2012 and No. 2013-146968, filed on Jul. 12, 2013, the entire contents of which are incorporated herein by reference.

### BACKGROUND

1. Field

Embodiments described herein relate generally to a power semiconductor device and a method of manufacturing a power semiconductor device.

2. Background Art

A power semiconductor device according to prior art has deep diffusion layers formed side by side in a termination region thereof so that extension of a depletion layer in a horizontal direction in the termination region is adjusted and the element withstand voltage is maintained. In addition, an oxide film is stacked on the silicon substrate to form an electrode serving as a field plate or the like, thereby maintaining the static withstand voltage.

### BRIEF DESCRIPTION OF THE DRAWINGS

FIG. 1 is a cross-sectional view showing an example of a configuration of a power semiconductor device 100 according to a first embodiment;

FIG. 2 is a diagram for illustrating a step of the method of manufacturing the power semiconductor device shown in FIG. 1;

FIG. 3 is a diagram for illustrating a step of the method of manufacturing the power semiconductor device shown in FIG. 1, in a process subsequent to that shown in FIG. 2;

FIG. 4 is a diagram for illustrating a step of the method of manufacturing the power semiconductor device shown in FIG. 1, in a process subsequent to that shown in FIG. 3;

FIG. 5 is a diagram for illustrating a step of the method of manufacturing the power semiconductor device shown in FIG. 1, in a process subsequent to that shown in FIG. 4;

FIG. 6 is a diagram for illustrating a step of the method of manufacturing the power semiconductor device shown in FIG. 1, in a process subsequent to that shown in FIG. 5;

FIG. 7 is a diagram for illustrating a step of the method of manufacturing the power semiconductor device shown in FIG. 1, in a process subsequent to that shown in FIG. 6;

FIG. 8 is a diagram for illustrating a step of the method of manufacturing the power semiconductor device shown in FIG. 1, in a process subsequent to that shown in FIG. 7;

FIG. 9 is a diagram for illustrating a step of the method of manufacturing the power semiconductor device shown in FIG. 1, in a process subsequent to that shown in FIG. 8;

FIG. 10 is a diagram for illustrating a step of the method of manufacturing the power semiconductor device shown in FIG. 1, in a process subsequent to that shown in FIG. 9;

FIG. 11 is a diagram for illustrating a step of the method of manufacturing the power semiconductor device shown in FIG. 1, in a process subsequent to that shown in FIG. 10;

FIG. 12 is a diagram for illustrating a step of the method of manufacturing the power semiconductor device shown in FIG. 1, in a process subsequent to that shown in FIG. 11;

FIG. 13 is a diagram for illustrating a step of the method of manufacturing the power semiconductor device shown in FIG. 1, in a process subsequent to that shown in FIG. 12;

FIG. 14 is a diagram for illustrating a step of the method of manufacturing the power semiconductor device shown in FIG. 1, in a process subsequent to that shown in FIG. 13;

FIG. 15 is a diagram for illustrating a step of the method of manufacturing the power semiconductor device shown in FIG. 1, in a process subsequent to that shown in FIG. 14;

FIG. 16 is a diagram for illustrating a step of the method of manufacturing the power semiconductor device shown in FIG. 1, in a process subsequent to that shown in FIG. 15;

FIG. 17 is a diagram for illustrating a step of the method of manufacturing the power semiconductor device shown in FIG. 1, in a process subsequent to that shown in FIG. 16;

FIG. 18 is a cross-sectional view showing an example of a configuration of a power semiconductor device 200 according to a second embodiment;

FIG. 19 is a cross-sectional view showing an example of a configuration of a power semiconductor device 300 according to a third embodiment; and

FIG. 20 is a cross-sectional view showing an example of a configuration of a power semiconductor device 400 according to a fourth embodiment.

### DETAILED DESCRIPTION

A power semiconductor device according to an embodiment includes a semiconductor substrate of a first conductivity type. The power semiconductor device an element formed in a cell region of the semiconductor substrate. The power semiconductor device a plurality of first diffusion layers of a second conductivity type formed in an upper surface of a termination region, which is located along an outer periphery of the cell region of an upper surface of the semiconductor substrate. The power semiconductor device a first oxide film formed in a first region of the termination region of the semiconductor substrate, the first region being spaced apart from the first diffusion layers. The power semiconductor device a second oxide film formed in an upper surface of the termination region of the semiconductor substrate including the first oxide film and the first diffusion layers. The power semiconductor device an electrode formed on the second oxide film so as to extend from the first region toward the cell region to the first diffusion layers. The power semiconductor device a third oxide film formed on the second oxide film and the electrode. The power semiconductor device a connection electrode that is formed on the third oxide film and in the second and third oxide films and electrically connects the electrode to the first diffusion layers that are located adjacent to the electrode on the side closer to the cell region. The level of an upper surface of the electrode is lower than the level of the upper surface of the semiconductor substrate in the cell region.

A termination region formed by deep diffusion layers arranged side by side according to prior art requires a high-temperature long-time thermal processing step.

On the other hand, in a downsizing process, such as a CMOS process and a memory process, a deep diffusion layer, and therefore a high-temperature long-time diffusion step, is not necessary. It is enough to form a shallow diffusion layer.

If the downsizing process is used to downsize the power semiconductor device while maintaining the withstand voltage of the power semiconductor device, the withstand voltage has to be maintained with the shallow diffusion layer. To achieve this, there is a possibility that the area and length of the termination region be extremely large.

An example of a power semiconductor device that can be downsized and an example of a method of manufacturing the power semiconductor device will be described with regard to an embodiment.

In the following, the embodiment will be described with reference to the drawings.

### First Embodiment

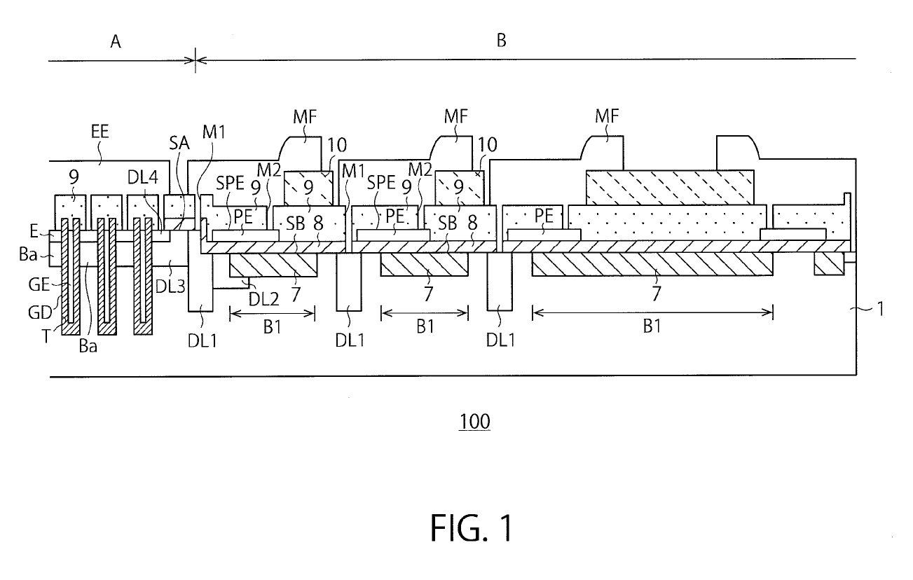

FIG. 1 is a cross-sectional view showing an example of a configuration of a power semiconductor device 100 according to a first embodiment.

As shown in FIG. 1, the power semiconductor device 100 includes a semiconductor substrate 1 of a first conductivity type (n type), and the semiconductor substrate 1 has a cell region “A” on which an insulated gate bipolar transistor (IGBT) element is mounted and a termination region “B” located along an outer periphery of the cell region “A”.

The termination region “B” has a plurality of first diffusion layers “DL1” of a second conductivity type (p type), a reduced surface field (RESURF) structure (second diffusion layer) “DL2”, a first oxide film 7, a second oxide film 8, a third oxide film 9, a fourth oxide film 10, an electrode “PE” and a connection electrode “MF”.

The semiconductor substrate 1 is a silicon substrate, for example. In the case where a diode is formed, only a diffusion layer of the second conductivity type is formed in the cell region “A”. Alternatively, both an IGBT and a diode may be formed. In that case, an anode region of the diode is formed in the cell region “A”.

The IGBT element is formed in the cell region “A” of the semiconductor substrate 1. The IGBT element has a gate insulating film “GD” provided on an inner surface of a trench “T” formed in the semiconductor substrate 1, a gate electrode “GE” provided in the trench “T” with the gate insulating film “GD” interposed between the gate electrode “GE” and the inner surface of the trench “T”, a base layer “Ba” of the first conductivity type (n type) formed in the semiconductor substrate 1, an emitter layer “E” of the first conductivity type (p type) formed in the semiconductor substrate 1, and an emitter electrode “EE” provided on the semiconductor substrate 1.

A collector electrode of the IGBT element (not shown) is provided on the lower side (bottom surface) of the semiconductor substrate 1.

The plurality of first diffusion layers “DL1” is formed in the upper surface of the termination region “B” located along the outer periphery of the cell region “A” of the upper surface of the semiconductor substrate 1.

The first oxide film 7 is formed in a first region “B1”, which is spaced apart from the first diffusion layers “DL1”, of the termination region “B” of the semiconductor substrate 1.

The second oxide film 8 is formed on the upper surface of the termination region “B” of the semiconductor substrate 1 including the first oxide film 7 and the first diffusion layer “DL1”.

The electrode “PE” is formed on the second oxide film 8 to extend from on the first region “B1” toward the cell region “A” to the first diffusion layer “DL1”. The electrode “PE” is formed by a polysilicon film, for example. For example, a ground potential is applied to the electrode “PE”. As described later, the electrode

“PE” serves to stabilize potential and facilitate extension of a depletion layer in a horizontal direction from the cell region “A” toward the outer periphery when a reverse bias is applied to the power semiconductor device 100.

The third oxide film 9 is formed on the second oxide film 8 and the electrode “PE”. In the third oxide film 9, a second through-hole “M2” that penetrates the third oxide film 9 and reaches a surface “SPE” of the electrode “PE” is formed.

In the second oxide film 8 and the third oxide film 9, a first through-hole “Ml” that penetrates the second oxide film 8 and the third oxide film 9 and reaches the surface of the first diffusion layer “DL1” is formed.

The fourth oxide film 10 is formed between the third insulating film 9 and the connection electrode “MF”.

The connection electrode “MF” is formed on the third oxide film 9 between the first through-hole “M1” and the second through-hole “M2” and is buried in the first through-hole “M1” and the second through-hole “M2”. The connection electrode “MF” is a metal electrode, for example.

The connection electrode “MF” is configured to electrically connect the electrode “PE” to the adjacent first diffusion layer “DL1” located on the side closer to the cell region “A”. That is, the connection electrode “MF” equalizes the potential at the first diffusion layer “DL1” and the potential at the electrode “PE”.

The power semiconductor device 100 has the RESURF structure (second diffusion layer) “DL2” in the termination region “B” surrounding the cell region “A”. The RESURF structure “DL2” is a structure that allows a depletion layer to extend in a horizontal direction from the cell region “A” toward the outer periphery to maintain the withstand voltage when a reverse bias is applied. The RESURF structure “DL2” facilitates extension of the depletion layer even if the resistivity of the substrate is relatively low. In addition, according to this embodiment, a high withstand voltage can be achieved even if the area and the horizontal length of the termination region “B” are small, so that the packaging density of the power semiconductor device 100 can be improved.

In particular, as described above, the level of the upper surface “SPE” of the electrode “PE” is lower than the level of an upper surface “SA” of the semiconductor substrate 1 in the cell region “A”. That is, since the electrode “PE” forming the termination region “B” is buried in the silicon substrate 1, the level difference in the termination region “B” is reduced, a planarization process, such as a chemical mechanical polishing (CMP) process, can be used, and the power semiconductor device 100 can be downsized. As a result, the compatibility with a memory process intended for downsizing is also improved.

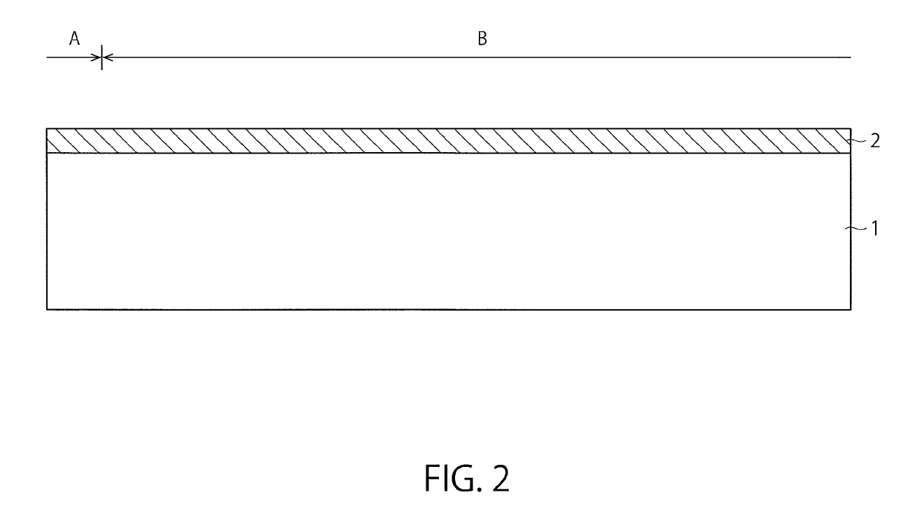

Next, an example of a method of manufacturing the power semiconductor device 100 configured as described above will be described. FIGS. 2 to 17 are diagrams for illustrating steps of the method of manufacturing the power semiconductor device shown in FIG. 1. FIGS. 2 to 17 particularly show the termination region of the power semiconductor device.

First, as shown in FIG. 2, an oxide film 2 is formed on a semiconductor substrate (silicon substrate) 1 of a first conductivity type (n type) in a thermal oxidation process, for example.

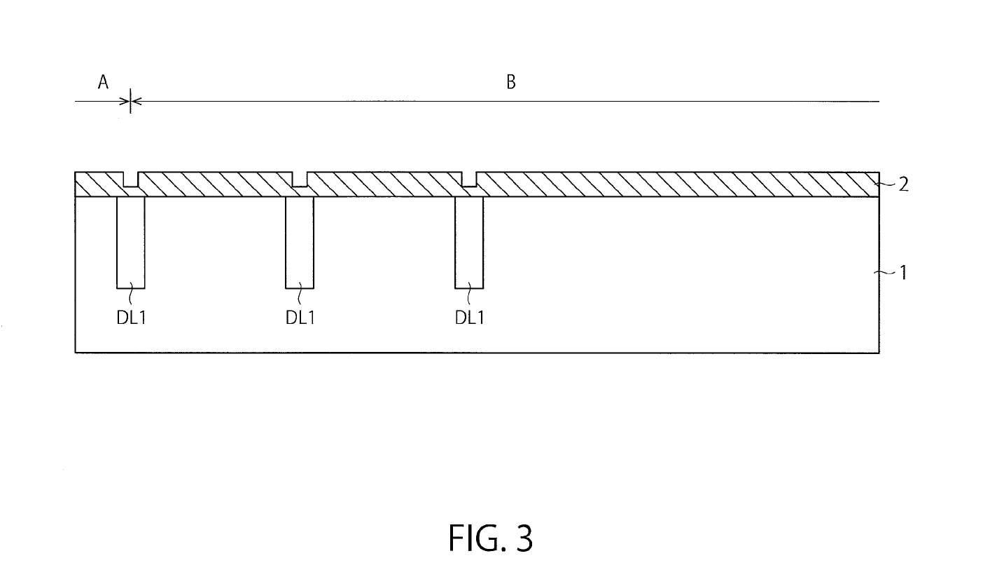

Next, as shown in FIG. 3, upper parts of the oxide film 2 corresponding to regions where first diffusion layers “DL1” are to be formed are selectively etched. Next, an impurity is injected into the semiconductor substrate 1 through the oxide film 2 in an ion injection process. Furthermore, the impurity is diffused in a heating process to form a plurality of first diffusion layers “DL1”.

In this way, of the upper surface of the semiconductor substrate 1 of the first conductivity type (n type), in the upper surface of a termination region “B” located along the outer periphery of a cell region “A” of the semiconductor substrate 1, a plurality of first diffusion layers “DL1” of a second conductivity type (p type) is formed. Note that the plurality of first diffusion layers “DL1” formed extend in parallel with the boundary between the cell region “A” and the termination region “B”.

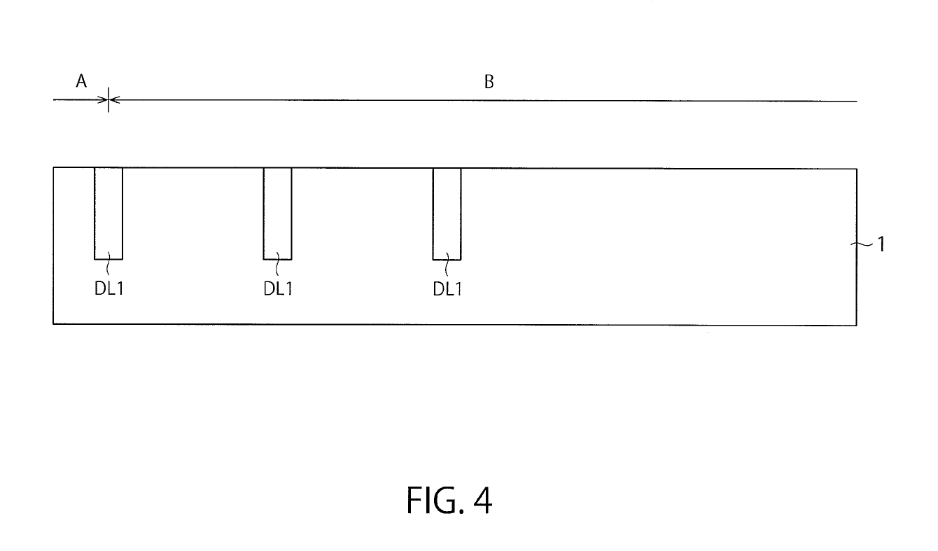

Next, as shown in FIG. 4, the insulating film 2 on the semiconductor substrate 1 is removed.

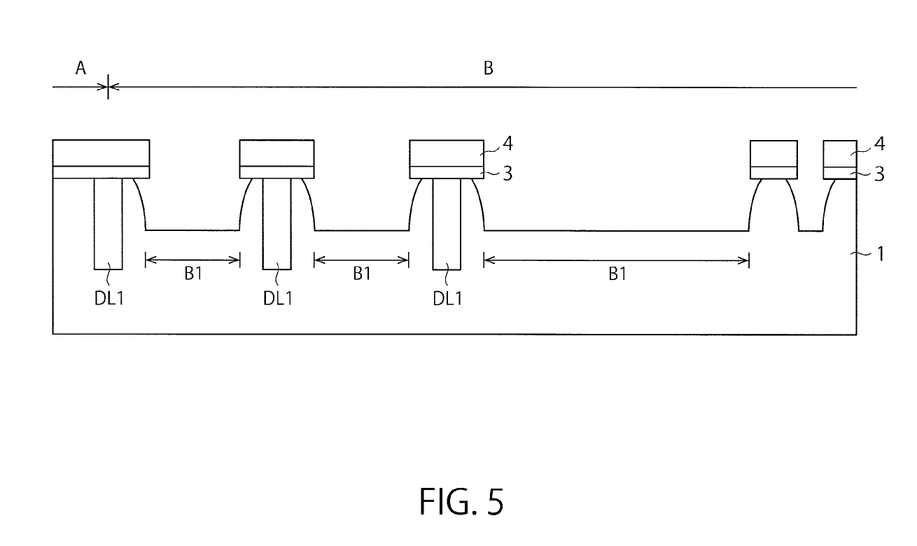

Next, as shown in FIG. 5, oxide films 3 and 4 are deposited on the semiconductor substrate 1 in the thermal oxidation process and a chemical vapor deposition (CVD) process. Next, the oxide films 3 and 4 are selectively etched by lithography in such a manner that the oxide films 3 and 4 remain in the cell region “A” and the regions in which the first diffusion layers “DL1” are formed. Next, using the remaining oxide films 3 and 4 as masks, the surface of the semiconductor substrate is selectively etched in a chemical dry etching (CDE) process.

That is, of the upper surface of the termination region “B” of the semiconductor substrate 1, the upper surface of the semiconductor substrate 1 is selectively etched in first regions (regions between adjacent first diffusion layers “DL1”) “B1” each extending for a predetermined distance from a first diffusion layer “DL1” on the side opposite to the cell region “A”.

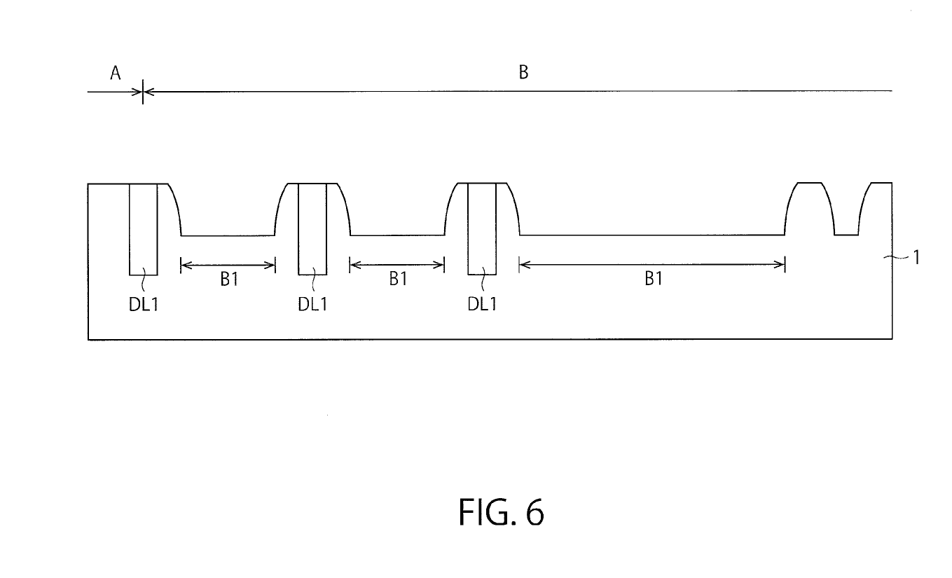

Next, as shown in FIG. 6, the oxide films 3 and 4 are removed from the semiconductor substrate 1.

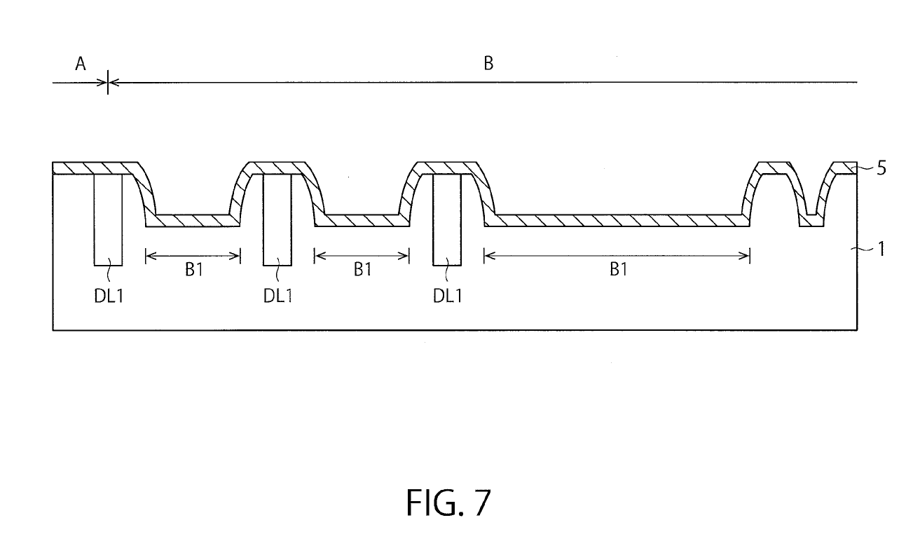

Next, as shown in FIG. 7, an oxide film 5 is deposited on the semiconductor substrate 1 in the thermal oxidation process, for example. Next, an impurity of the p type is injected into the semiconductor substrate 1 at a part on the side, closer to the termination region “B”, of the first diffusion layer “DL1” located at the boundary between the cell region “A” and the termination region “B” through the oxide film 5 in the ion injection process.

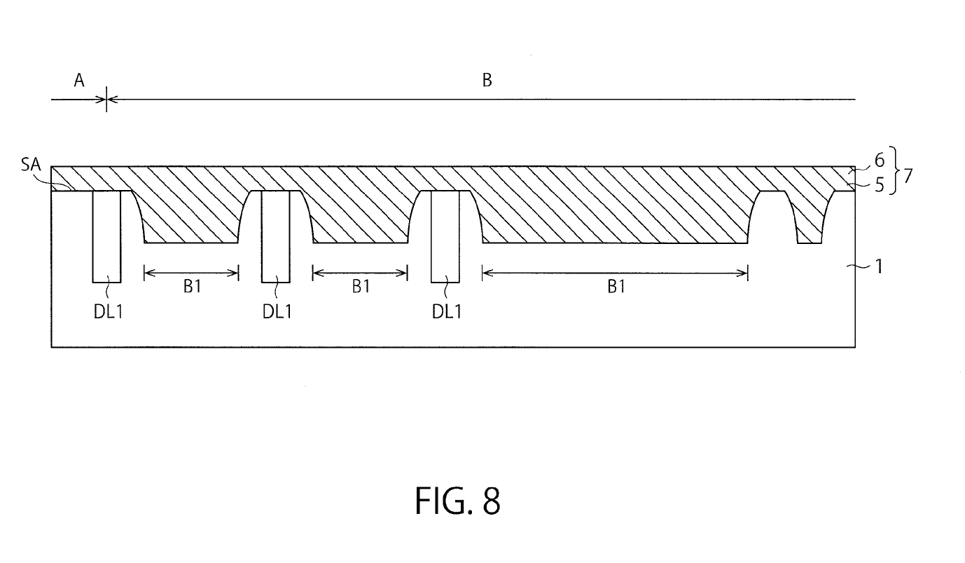

Next, as shown in FIG. 8, an oxide film 6 is deposited on the oxide film 5 in the CVD process, for example.

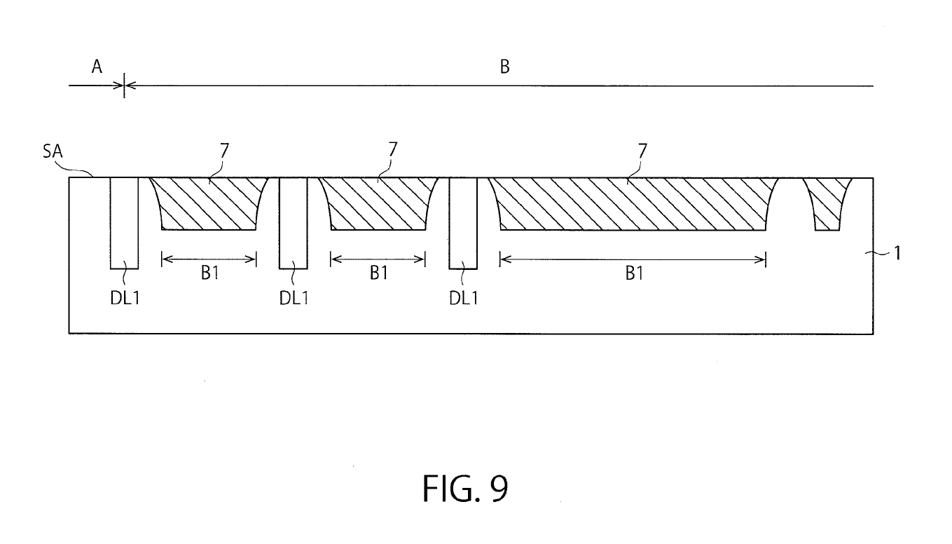

Next, as shown in FIG. 9, a first oxide film (insulating film) 7 (formed by the oxide films 5 and 6) is planarized in the CMP process until the level of the upper surface of the first oxide film 7 is flush with the upper surface of the semiconductor substrate 1.

Through the steps shown in FIGS. 7 to 9 described above, the first oxide film 7 is selectively formed on the upper surface of the semiconductor substrate 1 with the first regions “B1” etched.

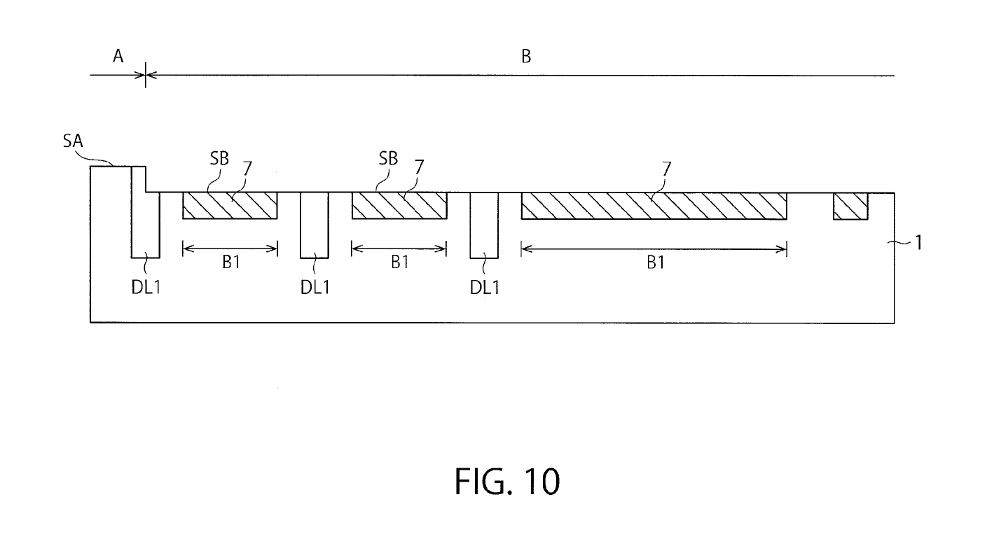

Next, as shown in FIG. 10, the upper surface of the semiconductor substrate 1, the upper surface of the first diffusion layers “DL1” and the upper surface of the first oxide films 7 are etched in the termination region “B” so that the level of an upper surface “SB” of the semiconductor substrate 1 including the first oxide films 7 and the first diffusion layers “DL1” in the termination region “B” is lower than the level of the upper surface “SA” of the semiconductor substrate 1 in the cell region “A”.

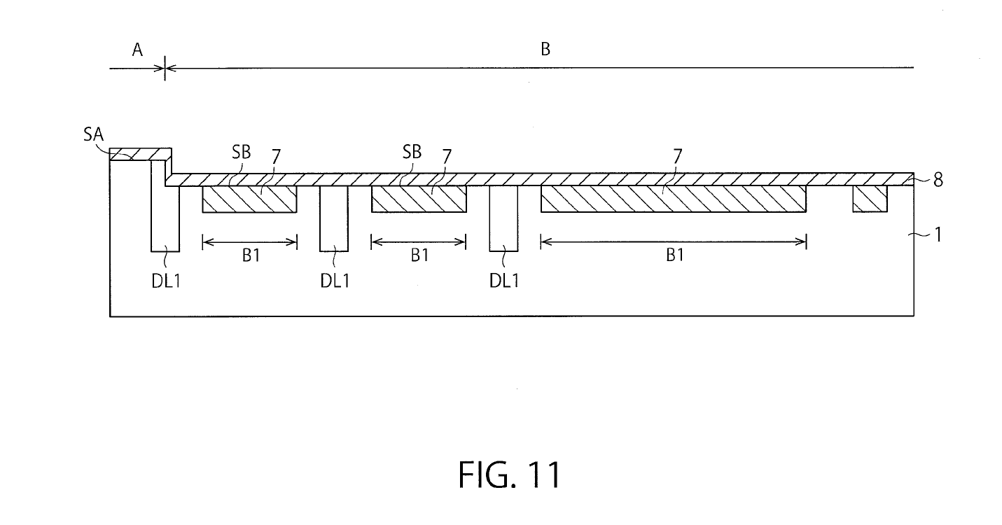

Next, as shown in FIG. 11, a second oxide film (insulating film) 8 is formed on the semiconductor substrate 1.

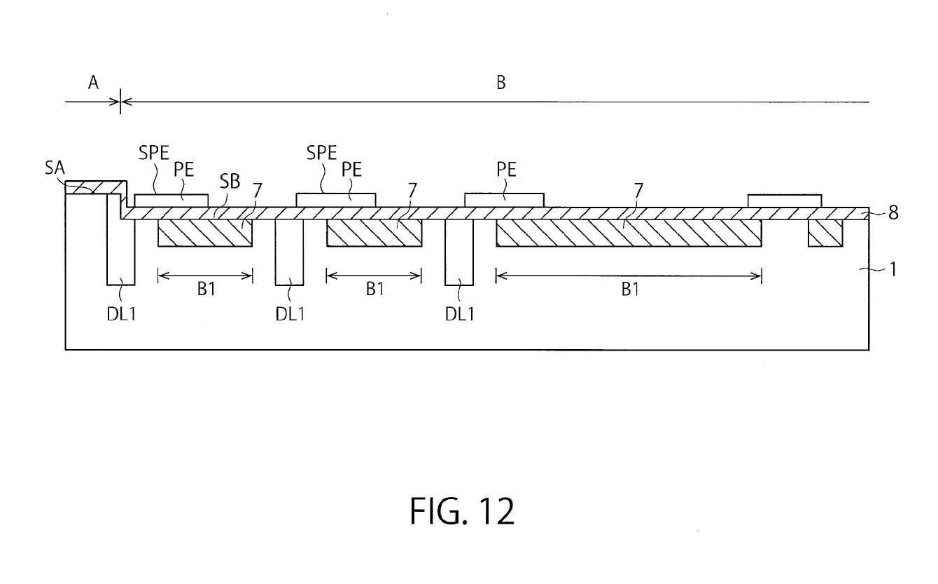

Next, as shown in FIG. 12, electrodes “PE” extending from the first regions “B1” (first oxide films 7) to the respective first diffusion layers “DL1” on the side closer to the cell region “A” are formed on the second oxide film 8 in such a manner that the level of upper surfaces “SPE” of the electrodes “PE” is lower than the level of the upper surface “SA” of the semiconductor substrate 1 in the cell region “A”.

As a result, the level difference between the cell region “A” and the termination region “B” is reduced, and a planarization technique, such as the CMP process, can be used in the subsequent steps

Next, an impurity of the p type is selectively injected into the semiconductor substrate 1 at a part on the side, closer to the cell region “A”, of the first diffusion layer “DL1” located at the boundary between the cell region “A” and the termination region “B” through the oxide film 5 in the ion injection process.

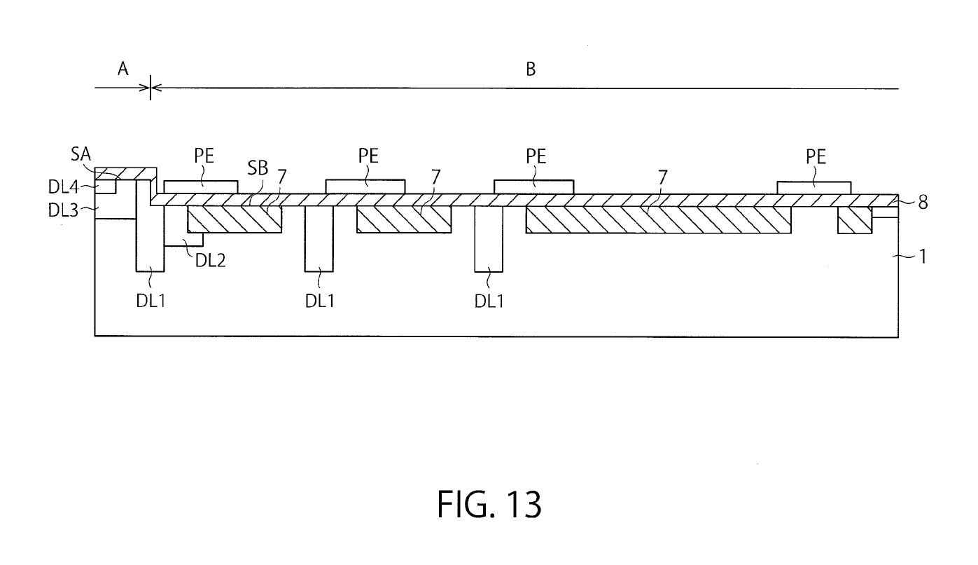

Next, as shown in FIG. 13, a second diffusion layer “DL2” of the p type, a third diffusion layer “DL3” of the p type, and a fourth diffusion layer “DL4” of the p type are formed through diffusion of an impurity in a thermal diffusion process, for example.

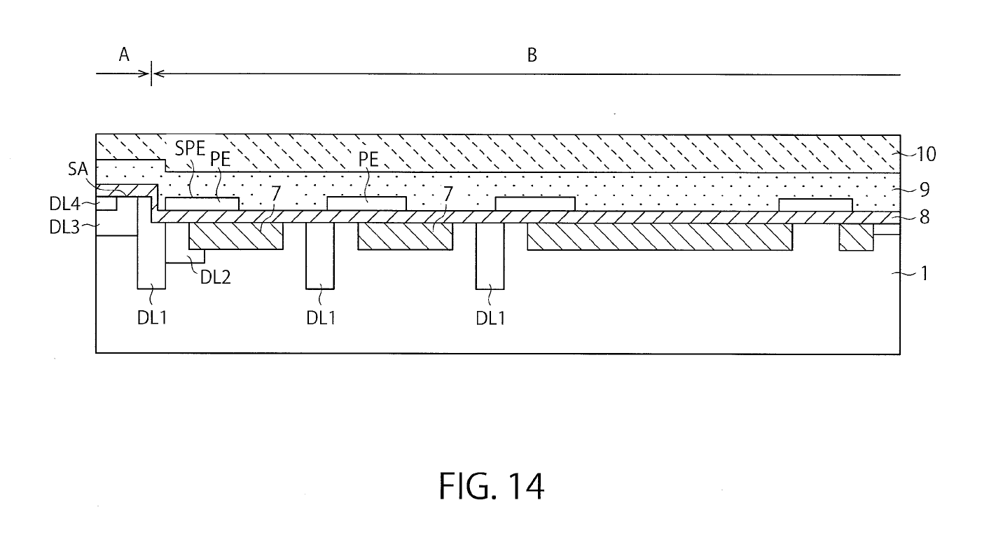

Next, as shown in FIG. 14, after the electrodes “PE” are formed, a third oxide film (insulating film) 9 is formed on the second oxide film 8 and the electrodes “PE” in the CVD process, for example. Furthermore, after the third oxide film 9 is formed, a fourth oxide film (insulating film) 10 is formed on the third oxide film 9.

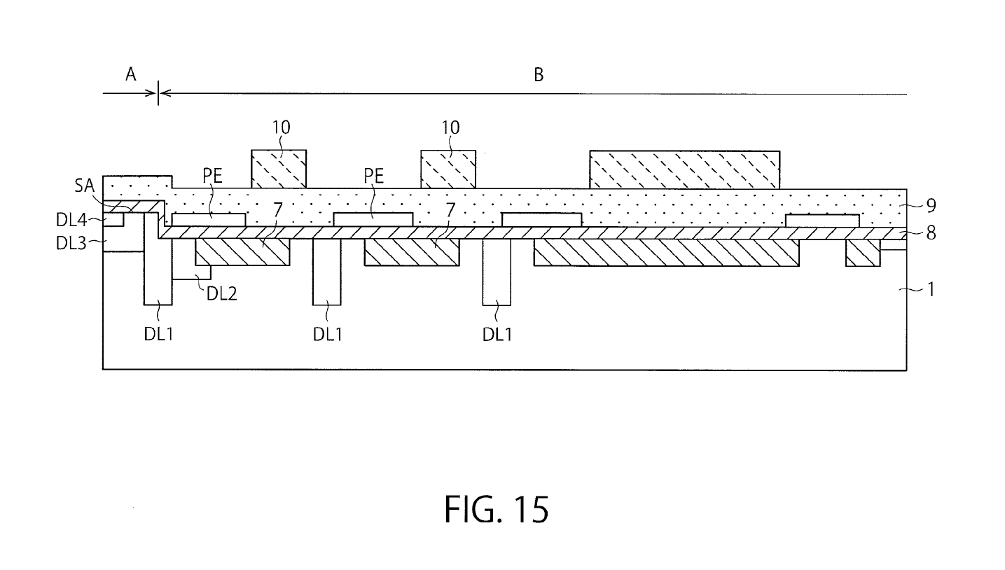

Next, as shown in FIG. 15, the fourth oxide film 10 is selectively etched.

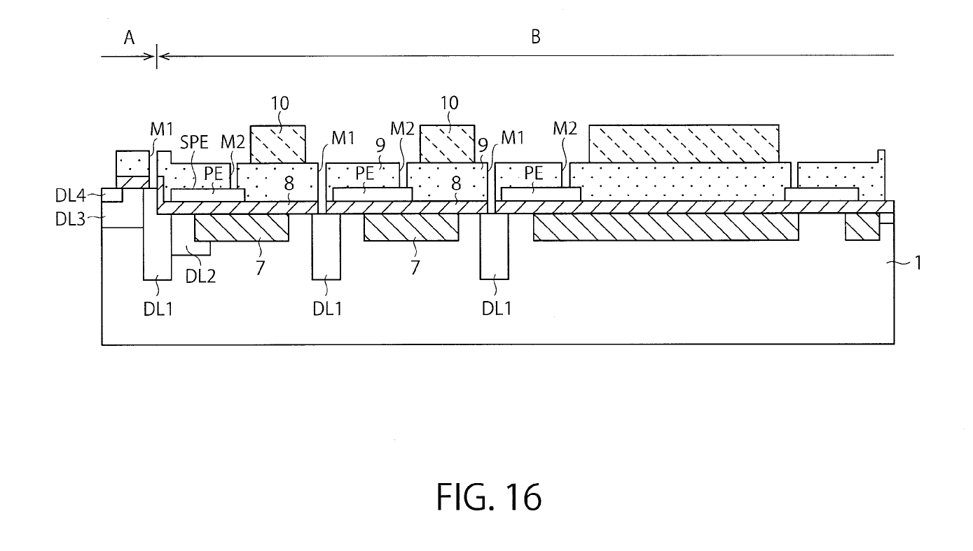

Next, as shown in FIG. 16, the second oxide film 8 and the third oxide film 9 are selectively etched to form first through-holes “M1” that reach the surfaces of the first diffusion layers “DL1”, and the second oxide film 8 is selectively etched to form second through-holes “M2” that reach the surfaces “SPE” of the electrodes “PE”.

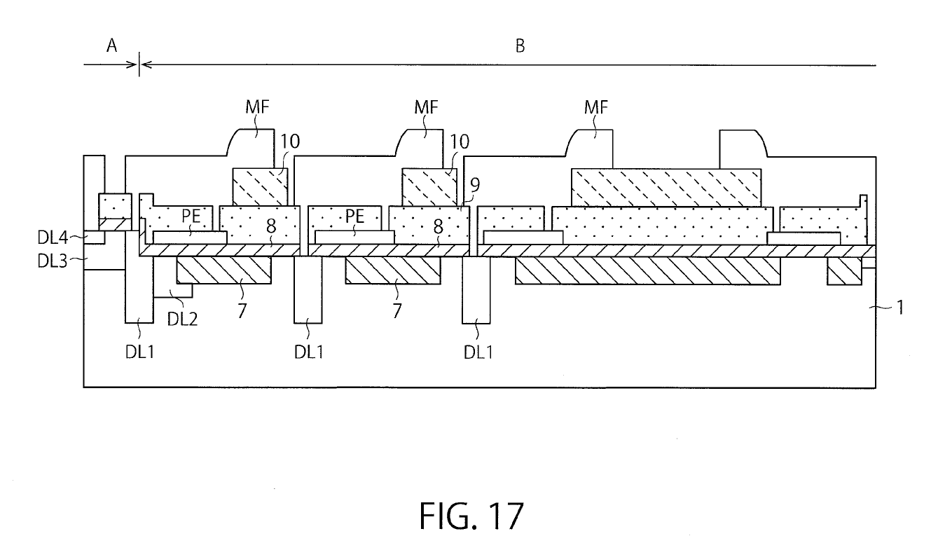

Next, as shown in FIG. 17, connection electrodes “MF” are formed on the second oxide film 8 between the second through-holes “M2” and the first through-holes “M1” and buried in the first through-holes “M1” and the second through-holes “M2” so as to electrically connect the electrodes “PE” to the respective adjacent first diffusion layers “DL1” located on the side closer to the cell region “A”.

Next, a passivation film (not shown) serving as a protective film is deposited.

Through the steps described above, the structure in the termination region “B” of the power semiconductor device 100 shown in FIG. 1 is completed.

As described above, in the termination region “B” of the power semiconductor device 100, the level difference due to the oxide films and polysilicon films stacked one another decreases. Therefore, a planarization technique used for LSI or the like can be used.

As described above, according to the method of manufacturing the power semiconductor device according to this embodiment, downsizing of the power semiconductor device can be achieved.

### Second Embodiment

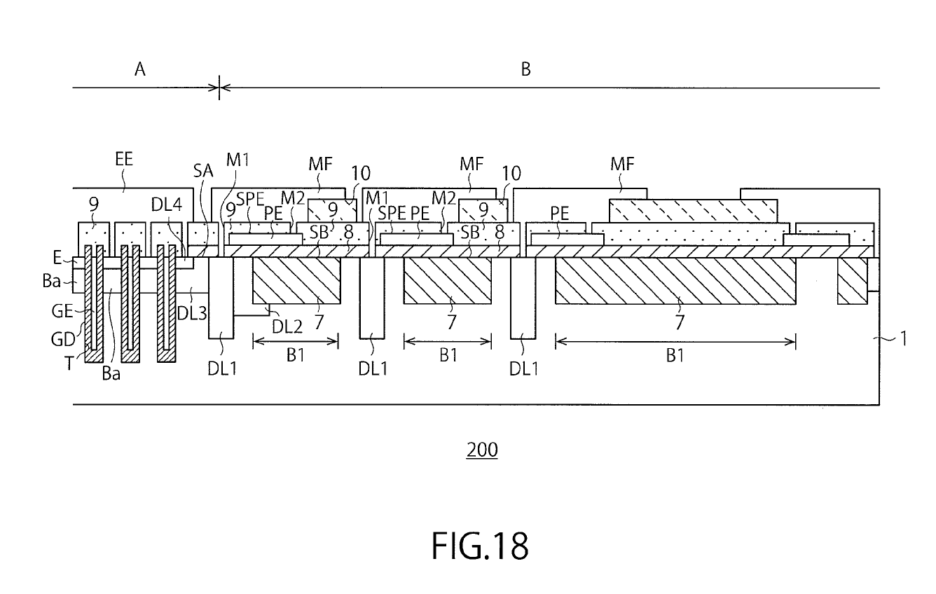

FIG. 18 is a cross-sectional view showing an example of a configuration of a power semiconductor device 200 according to a second embodiment.

As shown in FIG. 18, the power semiconductor device 200 includes a semiconductor substrate 1 of a first conductivity type (n type), and the semiconductor substrate 1 has a cell region “A” on which an IGBT element is mounted and a termination region “B” located along an outer periphery of the cell region “A”.

The termination region “B” has a plurality of first diffusion layers “DL1” of a second conductivity type (p type), a reduced surface field (RESURF) structure (second diffusion layer) “DL2”, a first oxide film 7, a second oxide film 8, a third oxide film 9, a fourth oxide film 10, a electrode “PE” and a connection electrode “MF”.

The semiconductor substrate 1 is a silicon substrate, for example. In the case where a diode is formed, only a diffusion layer of the second conductivity type is formed in the cell region “A”. Alternatively, both an IGBT and a diode may be formed. In that case, an anode region of the diode is formed in the cell region “A”.

The IGBT element is formed in the cell region “A” of the semiconductor substrate 1. The IGBT element has a gate insulating film “GD” provided on an inner surface of a trench “T” formed in the semiconductor substrate 1, a gate electrode “GE” provided in the trench “T” with the gate insulating film “GD” interposed between the gate electrode “GE” and the inner surface of the trench “T”, a base layer “Ba” of the first conductivity type (n type) formed in the semiconductor substrate 1, an emitter layer “E” of the first conductivity type (p type) formed in the semiconductor substrate 1, and an emitter electrode “EE” provided on the semiconductor substrate 1.

A collector electrode of the IGBT element (not shown) is provided on the lower side (bottom surface) of the semiconductor substrate 1.

The plurality of first diffusion layers “DL1” is formed in the upper surface of the termination region “B” located along the outer periphery of the cell region “A” of the upper surface of the semiconductor substrate 1.

The first oxide film 7 is formed in a first region “B1”, which is spaced apart from the first diffusion layers “DL1”, of the termination region “B” of the semiconductor substrate 1.

The second oxide film 8 is formed on the upper surface of the termination region “B” of the semiconductor substrate 1 including the first oxide film 7 and the first diffusion layer “DL1”. The electrode “PE” is formed on the second oxide film 8 to extend from on the first region “B1” toward the cell region “A” to the first diffusion layer “DL1”. The electrode “PE” is formed by a polysilicon film, for example. For example, a ground potential is applied to the electrode “PE”. As described later, the electrode “PE” serves to stabilize potential and facilitate extension of a depletion layer in a horizontal direction from the cell region “A” toward the outer periphery when a reverse bias is applied to the power semiconductor device 200.

In particular, the level of the lower surface of a second oxide film 8 is the same as the level of an upper surface “SA” of the semiconductor substrate 1 in the cell region “A”. The level of an upper surface “SPE” of the electrode “PE” is higher than the level of the upper surface “SA” of the semiconductor substrate 1 in the cell region “A”.

A third oxide film 9 is formed on the second oxide film 8 and the electrode “PE”. In the third oxide film 9, a second through-hole “M2” that penetrates the third oxide film 9 and reaches a surface “SPE” of the electrode “PE” is formed.

In the second oxide film 8 and the third oxide film 9, a first through-hole “Ml” that penetrates the second oxide film 8 and the third oxide film 9 and reaches a surface of a first diffusion layer “DL1” is formed.

A fourth oxide film 10 is formed between the third insulating film 9 and a connection electrode “MF”.

The connection electrode “MF” is formed on the third oxide film 9 between the first through-hole “M1” and the second through-hole “M2” and is buried in the first through-hole “M1” and the second through-hole “M2”. The connection electrode “MF” is a metal electrode, for example.

The connection electrode “MF” is configured to electrically connect the electrode “PE” to the adjacent first diffusion layer “DL1” located on the side closer to the cell region “A”. That is, the connection electrode “MF” equalizes the potential at the first diffusion layer “DL1” and the potential at the electrode “PE”.

The power semiconductor device 200 has the RESURF structure (second diffusion layer) “DL2” in the termination region “B” surrounding the cell region “A”. The RESURF structure “DL2” is a structure that allows a depletion layer to extend in a horizontal direction from the cell region “A” toward the outer periphery to maintain the withstand voltage when a reverse bias is applied. The RESURF structure “DL2” facilitates extension of the depletion layer even if the resistivity of the substrate is relatively low. In addition, according to this embodiment, a high withstand voltage can be achieved even if the area and the horizontal length of the termination region “B” are small, so that the packaging density of the power semiconductor device 200 can be improved.

As described above, according to the method of manufacturing the power semiconductor device according to this embodiment, downsizing of the power semiconductor device can be achieved.

### Third Embodiment

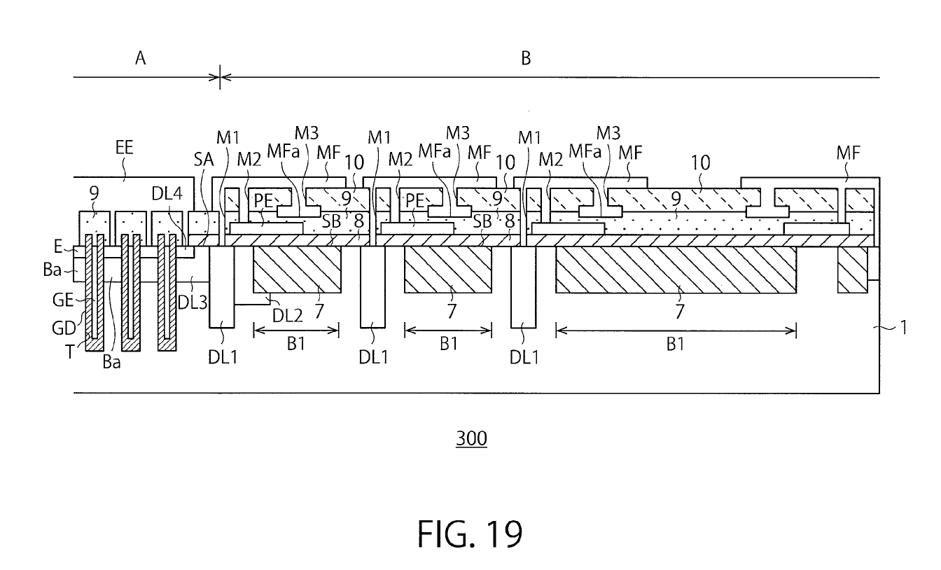

FIG. 19 is a cross-sectional view showing an example of a configuration of a power semiconductor device 300 according to a third embodiment.

As shown in FIG. 19, the power semiconductor device 300 includes a semiconductor substrate 1 of a first conductivity type (n type), and the semiconductor substrate 1 has a cell region “A” on which an IGBT element is mounted and a termination region “B” located along an outer periphery of the cell region “A”.

The termination region “B” has a plurality of first diffusion layers “DL1” of a second conductivity type (p type), a reduced surface field (RESURF) structure (second diffusion layer) “DL2”, a first oxide film 7, a second oxide film 8, a third oxide film 9, a fourth oxide film 10, an electrode “PE” and a connection electrode “MF”.

The semiconductor substrate 1 is a silicon substrate, for example. In the case where a diode is formed, only a diffusion layer of the second conductivity type is formed in the cell region “A”. Alternatively, both an IGBT and a diode may be formed. In that case, an anode region of the diode is formed in the cell region “A”.

The IGBT element is formed in the cell region “A” of the semiconductor substrate 1. The IGBT element has a gate insulating film “GD” provided on an inner surface of a trench “T” formed in the semiconductor substrate 1, a gate electrode “GE” provided in the trench “T” with the gate insulating film “GD” interposed between the gate electrode “GE” and the inner surface of the trench “T”, a base layer “Ba” of the first conductivity type (n type) formed in the semiconductor substrate 1, an emitter layer “E” of the first conductivity type (p type) formed in the semiconductor substrate 1, and an emitter electrode “EE” provided on the semiconductor substrate 1.

A collector electrode of the IGBT element (not shown) is provided on the lower side (bottom surface) of the semiconductor substrate 1.

The plurality of first diffusion layers “DL1” is formed in the upper surface of the termination region “B” located along the outer periphery of the cell region “A” of the upper surface of the semiconductor substrate 1.

The first oxide film 7 is formed in a first region “B1”, which is spaced apart from the first diffusion layers “DL1”, of the termination region “B” of the semiconductor substrate 1.

The second oxide film 8 is formed on the upper surface of the termination region “B” of the semiconductor substrate 1 including the first oxide film 7 and the first diffusion layer “DL1”.

The electrode “PE” is formed on the second oxide film 8 to extend from on the first region “B1” toward the cell region “A” to the first diffusion layer “DL1”. The electrode “PE” is formed by a polysilicon film, for example. For example, a ground potential is applied to the electrode “PE”. As described later, the electrode “PE” serves to stabilize potential and facilitate extension of a depletion layer in a horizontal direction from the cell region “A” toward the outer periphery when a reverse bias is applied to the power semiconductor device 300.

In particular, the level of the lower surface of a second oxide film 8 is the same as the level of an upper surface “SA” of the semiconductor substrate 1 in the cell region “A”. The level of an upper surface “SPE” of the electrode “PE” is higher than the level of the upper surface “SA” of the semiconductor substrate 1 in the cell region “A”.

A third oxide film 9 is formed on the second oxide film 8 and the electrode “PE”. In the third oxide film 9, a second through-hole “M2” that penetrates the third oxide film 9 and reaches a surface “SPE” of the electrode “PE” is formed.

In the second oxide film 8 and the third oxide film 9, a first through-hole “M1” that penetrates the second oxide film 8 and the third oxide film 9 and reaches a surface of a first diffusion layer “DL1” is formed.

A fourth oxide film 10 is formed between the third insulating film 9 and a connection electrode “MF”. The first through-hole “M1” and the second through-hole “M2” further penetrate the fourth oxide film 10. In the fourth oxide film 10, a third through-hole “M3” that penetrates the fourth oxide film 10 and reaches a recess “MFa” formed in a surface of the third oxide film 9 is formed.

The connection electrode “MF” is formed on the fourth oxide film 10 in areas between the first through-hole “Ml” and the second through-hole “M2” and between the second through-hole “M2” and the third through-hole “M3” and buried in the first through-hole “M1”, the second through-hole “M2”, the third through-hole “M3” and the recess “MFa”. The connection electrode “MF” is a metal electrode, for example.

The connection electrode “MF” is configured to electrically connect the electrode “PE” to the adjacent first diffusion layer “DL1” located on the side closer to the cell region “A”. That is, the connection electrode “MF” equalizes the potential at the first diffusion layer “DL1” and the potential at the electrode “PE”.

The power semiconductor device 300 has the RESURF structure (second diffusion layer) “DL2” in the termination region “B” surrounding the cell region “A”. The RESURF structure “DL2” is a structure that allows a depletion layer to extend in a horizontal direction from the cell region “A” toward the outer periphery to maintain the withstand voltage when a reverse bias is applied. The RESURF structure “DL2” facilitates extension of the depletion layer even if the resistivity of the substrate is relatively low. In addition, according to this embodiment, a high withstand voltage can be achieved even if the area and the horizontal length of the termination region “B” are small, so that the packaging density of the power semiconductor device 300 can be improved.

As described above, according to the method of manufacturing the power semiconductor device according to this embodiment, downsizing of the power semiconductor device can be achieved.

### Fourth Embodiment

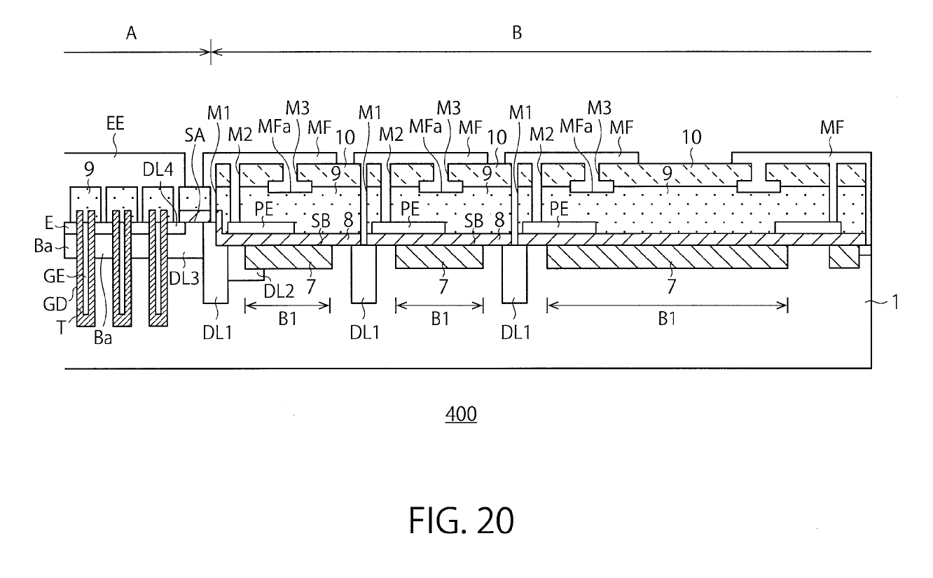

FIG. 20 is a cross-sectional view showing an example of a configuration of a power semiconductor device 400 according to a third embodiment.

As shown in FIG. 20, the power semiconductor device 400 includes a semiconductor substrate 1 of a first conductivity type (n type), and the semiconductor substrate 1 has a cell region “A” on which an IGBT element is mounted and a termination region “B” located along an outer periphery of the cell region “A”.

The termination region “B” has a plurality of first diffusion layers “DL1” of a second conductivity type (p type), a reduced surface field (RESURF) structure (second diffusion layer) “DL2”, a first oxide film 7, a second oxide film 8, a third oxide film 9, a fourth oxide film 10, an electrode “PE” and a connection electrode “MF”.

The semiconductor substrate 1 is a silicon substrate, for example. In the case where a diode is formed, only a diffusion layer of the second conductivity type is formed in the cell region “A”. Alternatively, both an IGBT and a diode may be formed. In that case, an anode region of the diode is formed in the cell region “A”.

The IGBT element is formed in the cell region “A” of the semiconductor substrate 1. The IGBT element has a gate insulating film “GD” provided on an inner surface of a trench “T” formed in the semiconductor substrate 1, a gate electrode “GE” provided in the trench “T” with the gate insulating film “GD” interposed between the gate electrode “GE” and the inner surface of the trench “T”, a base layer “Ba” of the first conductivity type (n type) formed in the semiconductor substrate 1, an emitter layer “E” of the first conductivity type (p type) formed in the semiconductor substrate 1, and an emitter electrode “EE” provided on the semiconductor substrate 1.

A collector electrode of the IGBT element (not shown) is provided on the lower side (bottom surface) of the semiconductor substrate 1.

The plurality of first diffusion layers “DL1” is formed in the upper surface of the termination region “B” located along the outer periphery of the cell region “A” of the upper surface of the semiconductor substrate 1.

The first oxide film 7 is formed in a first region “B1”, which is spaced apart from the first diffusion layers “DL1”, of the termination region “B” of the semiconductor substrate 1.

The second oxide film 8 is formed on the upper surface of the termination region “B” of the semiconductor substrate 1 including the first oxide film 7 and the first diffusion layer “DL1”.

The electrode “PE” is formed on the second oxide film 8 to extend from on the first region “B1” toward the cell region “A” to the first diffusion layer “DL1”. The electrode “PE” is formed by a polysilicon film, for example. For example, a ground potential is applied to the electrode “PE”. As described later, the electrode “PE” serves to stabilize potential and facilitate extension of a depletion layer in a horizontal direction from the cell region “A” toward the outer periphery when a reverse bias is applied to the power semiconductor device 400.

A third oxide film 9 is formed on the second oxide film 8 and the electrode “PE”. In the third oxide film 9, a second through-hole “M2” that penetrates the third oxide film 9 and reaches a surface “SPE” of the electrode “PE” is formed.

In the second oxide film 8 and the third oxide film 9, a first through-hole “M1” that penetrates the second oxide film 8 and the third oxide film 9 and reaches a surface of a first diffusion layer “DL1” is formed.

A fourth oxide film 10 is formed between the third insulating film 9 and a connection electrode “MF”. The first through-hole “M1” and the second through-hole “M2” further penetrate the fourth oxide film 10. In the fourth oxide film 10, a third through-hole “M3” that penetrates the fourth oxide film 10 and reaches a recess “MFa” formed in a surface of the third oxide film 9 is formed.

The connection electrode “MF” is formed on the fourth oxide film 10 in areas between the first through-hole “M1” and the second through-hole “M2” and between the second through-hole “M2” and the third through-hole “M3” and buried in the first through-hole “M1”, the second through-hole “M2”, the third through-hole “M3” and the recess “MFa”. The connection electrode “MF” is a metal electrode, for example.

The connection electrode “MF” is configured to electrically connect the electrode “PE” to the adjacent first diffusion layer “DL1” located on the side closer to the cell region “A”. That is, the connection electrode “MF” equalizes the potential at the first diffusion layer “DL1” and the potential at the electrode “PE”.

The power semiconductor device 400 has the RESURF structure (second diffusion layer) “DL2” in the termination region “B” surrounding the cell region “A”. The RESURF structure “DL2” is a structure that allows a depletion layer to extend in a horizontal direction from the cell region “A” toward the outer periphery to maintain the withstand voltage when a reverse bias is applied. The RESURF structure “DL2” facilitates extension of the depletion layer even if the resistivity of the substrate is relatively low. In addition, according to this embodiment, a high withstand voltage can be achieved even if the area and the horizontal length of the termination region “B” are small, so that the packaging density of the power semiconductor device 400 can be improved.

In particular, same as the first embodiment, the level of the upper surface “SPE” of the electrode “PE” is lower than the level of an upper surface “SA” of the semiconductor substrate 1 in the cell region “A”. That is, since the electrode “PE” forming the termination region “B” is buried in the silicon substrate 1, the level difference in the termination region “B” is reduced, a planarization process, such as the CMP process, can be used, and the power semiconductor device 400 can be downsized. As a result, the compatibility with a memory process intended for downsizing is also improved.

As described above, according to the method of manufacturing the power semiconductor device according to this embodiment, downsizing of the power semiconductor device can be achieved.

The embodiments are given for illustrative purposes, and the scope of the present invention is not limited thereto. The present invention can be applied to any elements other than the IGBT element, such as diodes and MOSFETs.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A power semiconductor device, comprising:
a semiconductor substrate of a first conductivity type;
an element formed in a cell region of the semiconductor substrate;
a plurality of first diffusion layers of a second conductivity type formed in an upper surface of a termination region, which is located along an outer periphery of the cell region of an upper surface of the semiconductor substrate;
a first oxide film formed in a first region of the termination region of the semiconductor substrate, the first region being spaced apart from the first diffusion layers;
a second oxide film formed in an upper surface of the termination region of the semiconductor substrate including the first oxide film and the first diffusion layers;
an electrode formed on the second oxide film so as to extend from the first region toward the cell region to the first diffusion layers;
a third oxide film formed on the second oxide film and the electrode; and
a connection electrode that is formed on the third oxide film and in the second and third oxide films and electrically connects the electrode to the first diffusion layers that are located adjacent to the electrode on the side closer to the cell region,
wherein a level of an upper surface of the electrode is lower than a level of the upper surface of the semiconductor substrate in the cell region.

2. The power semiconductor device according to claim 1, wherein the element is an IGBT element.

3. The power semiconductor device according to claim 1, wherein an anode region of a diode is formed in the cell region.

4. The power semiconductor device according to claim 2, wherein an anode region of a diode is formed in the cell region.

5. A method of manufacturing a power semiconductor device, comprising:
forming a plurality of first diffusion layers of a second conductivity type in an upper surface of a termination region of an upper surface of a semiconductor substrate of a first conductivity type, the termination region being located along an outer periphery of a cell region of the semiconductor substrate;
selectively etching an upper surface of a first region of the upper surface of the termination region of the semiconductor substrate, the first region being spaced apart from the first diffusion layers;
selectively forming a first oxide film in the etched upper surface of the first region of the semiconductor substrate;
etching an upper part of the termination region of the semiconductor substrate, an upper surface of the first diffusion layers and an upper surface of the first oxide film in such a manner that a level of the upper surface of the semiconductor substrate in the termination region including the first oxide film and the first diffusion layers is lower than a level of the upper surface of the semiconductor substrate in the cell region;
then forming a second oxide film on the semiconductor substrate; and
forming an electrode on the second oxide film so as to extend from the first region toward the cell region to the first diffusion layers in such a manner that the level of an upper surface of the electrode is lower than the level of the upper surface of the semiconductor substrate in the cell region.

6. The method of manufacturing a power semiconductor device according to claim 5, wherein after the electrode is formed, a third oxide film is formed on the second oxide film and the electrode.

7. The method of manufacturing a power semiconductor device according to claim 6, wherein after the third oxide film is formed, the second oxide film is selectively etched to form a second through-hole that reaches a surface of the electrode, and the second oxide film and the third oxide film are selectively etched to form a first through-hole that reaches a surface of the first diffusion layers, and
a connection electrode is formed on the second oxide film in an area between the second through-hole and the first through-hole and buried in the first and second through-holes so as to electrically connect the electrode to the first diffusion layers that are located adjacent to the electrode on the side closer to the cell region.

8. The method of manufacturing a power semiconductor device according to claim 5, wherein the electrode is formed by a polysilicon film.

9. The method of manufacturing a power semiconductor device according to claim 6, wherein the electrode is formed by a polysilicon film.

10. The method of manufacturing a power semiconductor device according to claim 5, wherein an IGBT element is formed in the cell region.

11. The method of manufacturing a power semiconductor device according to claim 6, wherein an IGBT element is formed in the cell region.

12. The method of manufacturing a power semiconductor device according to claim 5, wherein the semiconductor substrate is a silicon substrate.

13. The method of manufacturing a power semiconductor device according to claim 6, wherein the semiconductor substrate is a silicon substrate.

14. The method of manufacturing a power semiconductor device according to claim 5, wherein an anode region of a diode is formed in the cell region.

15. The method of manufacturing a power semiconductor device according to claim 6, wherein an anode region of a diode is formed in the cell region.

16. A power semiconductor device, comprising:
a semiconductor substrate of a first conductivity type;
an element formed in a cell region of the semiconductor substrate;
a plurality of first diffusion layers of a second conductivity type formed in an upper surface of a termination region, which is located along an outer periphery of the cell region of an upper surface of the semiconductor substrate;
a first oxide film formed in a first region of the termination region of the semiconductor substrate, the first region being spaced apart from the first diffusion layers;
a second oxide film formed in an upper surface of the termination region of the semiconductor substrate including the first oxide film and the first diffusion layers;
an electrode formed on the second oxide film so as to extend from the first region toward the cell region to the first diffusion layers;
a third oxide film formed on the second oxide film and the electrode; and
a connection electrode that is formed on the third oxide film and in the second and third oxide films and electrically connects the electrode to the first diffusion layers that are located adjacent to the electrode on the side closer to the cell region,
wherein a level of a lower surface of the second oxide film is the same as a level of the upper surface of the semiconductor substrate in the cell region.

17. The power semiconductor device according to claim 16, wherein the level of the upper surface of the electrode is higher than the level of the upper surface of the semiconductor substrate in the cell region.

18. The power semiconductor device according to claim 16, wherein the element is an IGBT element.

19. The power semiconductor device according to claim 17, wherein an anode region of a diode is formed in the cell region.

20. The power semiconductor device according to claim 18, wherein an anode region of a diode is formed in the cell region.
